(19) United States
(12) Patent Application Publication
(10) Pub. No.: US 2015/0062552 A1
(43) Pub. Date: Mar. 5, 2015

(54) STAGE APPARATUS AND ITS DRIVING METHOD

(71) Applicant: CANON KABUSHIKI KAISHA, Tokyo (JP)

(72) Inventor: Tsutomu Terao, Utsunomiya-shi (JP)

(21) Appl. No.: 14/474,411

(22) Filed: Sep. 2, 2014

(30) Foreign Application Priority Data
Sep. 4, 2013 (JP) 2013-182874
Jul. 31, 2014 (JP) 2014-156173

(51) Int. Cl. G03F 7/20

(52) U.S. Cl. CPC G03F 7/70758; G03F 7/70725
USPC 355/72

(57) ABSTRACT

Provided is a stage apparatus that includes a first stage configured to be movable by a predetermined stroke; a second stage configured to be movable on the first stage by a stroke shorter than the stroke of the first stage; and a controller configured to control a first driving unit, which changes the relative position of the second stage with respect to the first stage, or a second driving unit, which changes the position of the first stage, such that the relative position of the second stage with respect to the first stage is offset in the direction of movement of the first stage upon acceleration of the first stage whereas the relative position of the second stage with respect to the first stage is offset in a direction opposite to the direction of movement of the first stage upon deceleration of the first stage.

### BACKGROUND OF THE INVENTION

1. Field of the Invention

The present invention relates to a stage apparatus and its driving method.

2. Description of the Related Art

An exposure apparatus exposes a pattern of an original (reticle, mask, or the like) onto a photosensitive substrate (wafer, glass plate, or the like where the surface thereof is coated with a resist layer) via a projection optical system in a lithography step included in manufacturing steps for a semiconductor device, a liquid crystal display device, and the like. The exposure apparatus typically includes a stage apparatus that is movable while holding an object which is a substrate or an original. Japanese Patent Laid-Open No. 2003-22960 discloses a stage apparatus having a coarse movement stage which is movable in a long stroke in the X-Y plane direction and a fine movement stage which is mounted on the coarse movement stage and is capable of being driven in small amounts for the positioning with high precision. Here, the top plate of the fine movement stage on which a substrate is placed is positioned in the degree of freedom of six axes (X, Y, Z, ωx, ωy, and ωz) depending on the state of the surface shape of a substrate held thereon and the state of a pattern to be transferred. As an actuator for moving the fine movement stage, linear motors are employed for six axes and electromagnets for pulling the center of gravity are further auxiliary used in the X-axis and Y-axis directions along which a large force is required for acceleration or deceleration.

Each of strokes in the ωx-, ωy-, and ωz-axis which is the rotational direction of each axis of the fine movement stage is determined by the spacing between the coarse movement stage and the fine movement stage (e.g., the spacing between an electromagnet (E-core) on the coarse movement stage side and a magnetic substance (I-core) on the fine movement stage side facing thereto) in the traveling direction. Here, it is preferable that the stroke of the fine movement stage is wide so as to change its orientation as much as possible. The stage spacing needs to be increased in order to increase the stroke. On the other hand, for example, the thrust force of the electromagnet is inversely proportional to the square of the stage spacing on the principle of electromagnetics. In other words, the stage spacing increases with an increase in the stroke of the fine movement stage but a thrust force per unit current of the electromagnet decreases at the increased spacing. Thus, in order to obtain the same (uniform) thrust force even if the stage spacing increases, more current must be fed to the electromagnet, resulting in an increase in the amount of heat generated in the electromagnet.

### SUMMARY OF THE INVENTION

The present invention provides, for example, a stage apparatus that includes a coarse movement stage and a fine movement stage and is advantageous for reducing the amount of heat generated in an actuator for driving the fine movement stage while ensuring the stroke of the fine movement stage.

According to an aspect of the present invention, a stage apparatus is provided that includes a first stage configured to be movable by a predetermined stroke; a second stage configured to be movable on the first stage by a stroke shorter than the stroke of the first stage; a first driving unit configured to include an actuator which generates a thrust force between the first stage and the second stage and has a different thrust constant depending on the relative positions of the first stage and the second stage and to change the relative position of the second stage with respect to the first stage; a second driving unit configured to change the position of the first stage; and a controller configured to control the first driving unit or the second driving unit such that the relative position of the second stage with respect to the first stage is offset in the direction of movement of the first stage upon acceleration of the first stage whereas the relative position of the second stage with respect to the first stage is offset in a direction opposite to the direction of movement of the first stage upon deceleration of the first stage.

Further features of the present invention will become apparent from the following description of exemplary embodiments with reference to the attached drawings.

### BRIEF DESCRIPTION OF THE DRAWINGS

FIG. 1 is a diagram illustrating a configuration of a stage apparatus according to one embodiment of the present invention.

FIG. 2A is an exploded perspective view illustrating an actuator for driving a fine movement stage.

FIG. 2B is a plan view illustrating the positional relationship between electromagnets and magnetic substances shown in FIG. 2A.

FIG. 3 is a graph illustrating variation in thrust constant of the electromagnet relating to the fine movement stage.

FIG. 4A is a diagram illustrating the state of the coarse movement stage upon acceleration thereof immediately after start of movement of the coarse movement stage.

FIG. 4B is a diagram illustrating the state of the coarse movement stage at a constant speed.

FIG. 4C is a diagram illustrating the state of the coarse movement stage upon deceleration thereof.

FIG. 4D is a diagram illustrating the state of the coarse movement stage with it being rotated in the oz direction.

FIG. 5 is a graph illustrating variation in acceleration and a spacing d during a scan operation.

### DESCRIPTION OF THE EMBODIMENTS

Hereinafter, preferred embodiments of the present invention will be described with reference to the drawings.

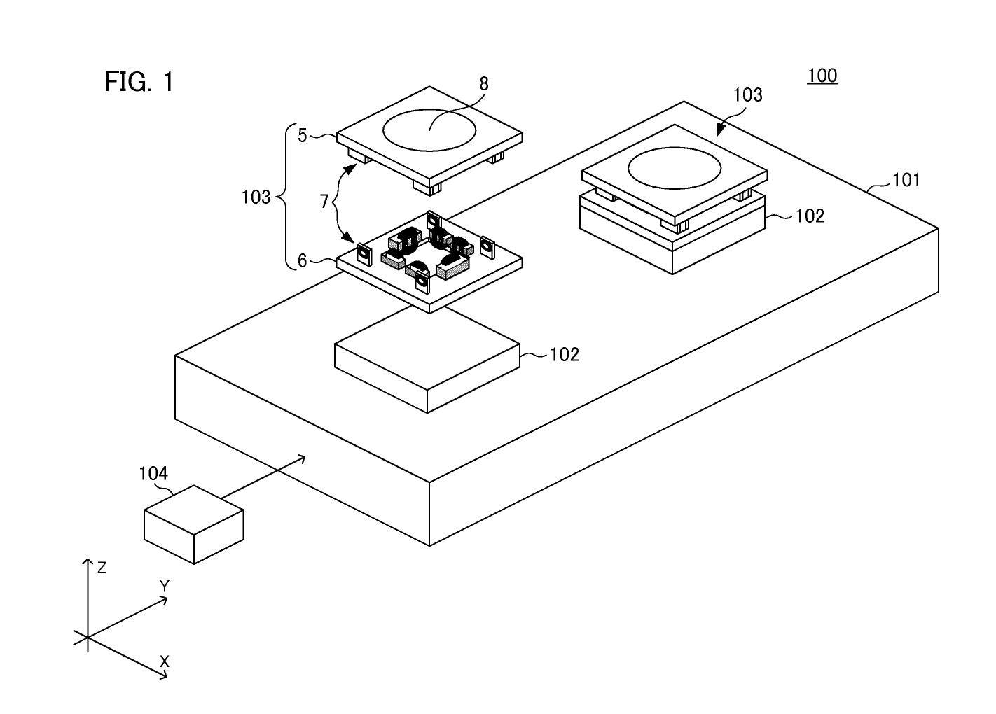

Firstly, a description will be given of a configuration of a stage apparatus according to a first embodiment of the present invention. The stage apparatus of the present embodiment may be employed as a device that is movable while holding a substrate such as a wafer or an original such as a reticle in a lithography apparatus such as an exposure apparatus or the like. Hereinafter, the stage apparatus of the present embodiment is intended to be a device that is movable while holding a wafer as an exemplary object to be held. FIG. 1 is a schematic perspective view illustrating a configuration of a stage apparatus 100 according to the present embodiment. In the following drawings, the Z axis is aligned in the vertical direction and the X-axis and the Y-axis are aligned mutually orthogonal to each other within a plane perpendicular to the Z-axis. The stage apparatus 100 includes a coarse movement stage (first stage) 102 that moves by a predetermined stroke in the X-axis and Y-axis directions on a platen 101, a fine movement stage (second stage) 103 that performs precision movement on the coarse movement stage 102 (on the coarse movement stage), and a controller 104. In the example shown in FIG. 1, the stage apparatus 100 is so-called a twin-stage type stage apparatus that has two pairs of the coarse movement stage 102 and the fine movement stage 103 such that these two pairs can be moved relative to each other on the platen 101 and are interchangeable with one another in any position. Note that the present invention is not limited thereto but the stage apparatus may be so-called a single-stage type stage apparatus that has a pair of the coarse movement stage 102 and the fine movement stage 103 or may also be a stage apparatus that has a plurality of pairs (three or more) of the coarse movement stage 102 and the fine movement stage 103. The following description will be given by taking an example of the configuration and the operation of a pair of the coarse movement stage 102 and the fine movement stage 103.

The coarse movement stage 102 is provided with the fine movement stage 103 (to be described below) at the top thereof and moves by a predetermined long stroke on the platen 101. Although not illustrated, a linear motor may be employed as a coarse movement actuator (second driving unit) for driving the coarse movement stage 102.

The fine movement stage 103 includes a top plate 5 having a rectangular plane shape, a base 6, and a fine movement actuator (first driving unit) 7 for causing the top plate 5 to move on the base 6 in the six-axis directions (X, Y, Z, ωx, ωy, and ωz) (change in orientation of the top plate 5). The top plate 5 is provided with (or integrated with) a chuck 8 for holding a wafer by suction for example and performs positioning of the wafer in the six-axis directions while holding it. The base 6 is fixed on the coarse movement stage 102, and both an electromagnet (actuator) of the fine movement actuator 7 to be described below and a stator 4 of the linear motor are provided on the base 6. In the present embodiment, there are two types of the fine movement actuator 7. Firstly, a linear motor is employed as an actuator that performs driving in the Z-axis direction and the tilt (ωx, ωy) direction among the six-axis directions. On the other hand, an electromagnet which is advantageous for suppressing heat generation per unit of thrust force is employed as an actuator that performs driving in the X-axis, Y-axis, and ωz-axis directions along which a thrust force (acceleration force) needs to be imparted to the top plate 5 upon acceleration thereof. Although not illustrated, a reflector plate (mirror) for reflecting light emitted from a laser interferometer is provided on the lateral surface of the top plate 5, and is used as a reference for measuring the position of the top plate 5.

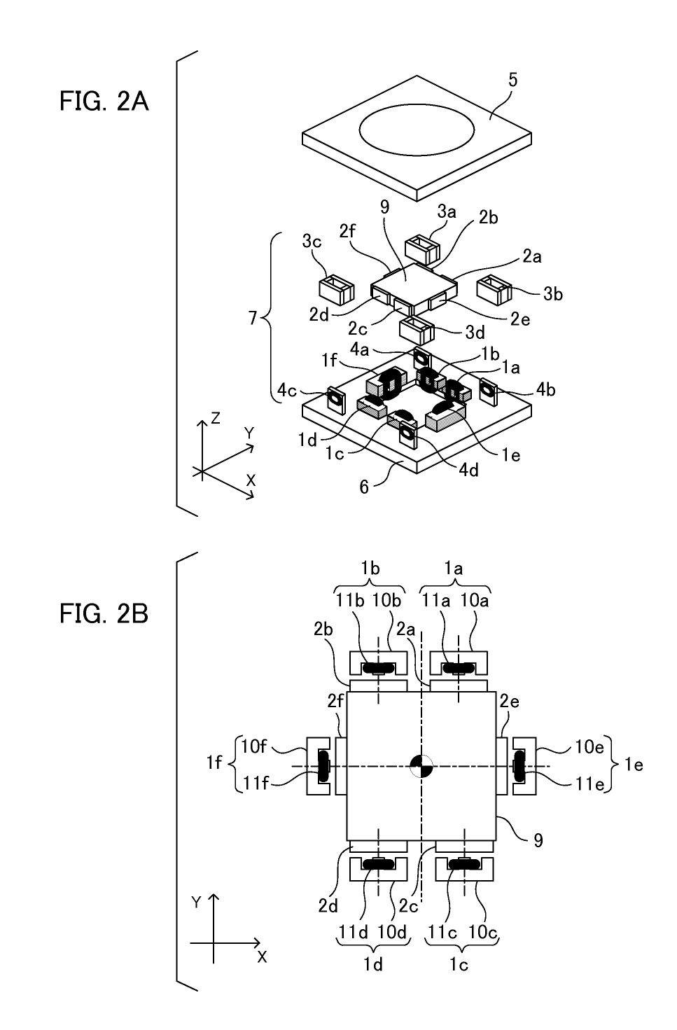

FIGS. 2A and 2B are schematic views illustrating a configuration of the fine movement actuator 7. FIG. 2A is an exploded perspective view illustrating the fine movement actuator 7. Firstly, a description will be given of a linear motor constituting the fine movement actuator 7. The linear motor consists of a pair of a movable element 3 which is fixed on the top plate 5 side and a stator 4 which is fixed on the base 6 side. A magnetic substance is mounted on the movable element 3, whereas a coil is mounted on the stator 4. In the present embodiment, as an example, four pairs in total of the linear motors are provided near the four ends (corners) of the top plate 5 having a rectangular plane shape. In FIG. 2A, among four pairs of the linear motors, four movable elements 3 are designated by reference numerals 3a to 3d, and four stators 4 corresponding thereto are designated by reference numerals 4a to 4d.

Next, a description will be given of the electromagnet 1 constituting the fine movement actuator 7. The electromagnet 1 includes a coil 11 that produces a magnetic field by the supply of control current and a yoke (E-core) 10 that forms a magnetic path between the yoke (E-core) 10 and a magnetic substance 2 (to be described below) by the produced magnetic field so as to increase a magnetic attraction force, and is fixed in plural (in the present embodiment, six electromagnets 1a to 1f) on the base 6 side. On the other hand, a plurality of magnetic substances (I-cores) 2 (magnetic substances 2a to 2f) corresponding to (in paired with) a plurality of the electromagnets 1a to 1f are provided on the other top plate 5 side. More specifically, a fixing member 9 having a plurality of magnetic substances 2 fixed at a specific spacing on four lateral surfaces thereof is provided on the central area of the backside of the top plate 5 (surface facing the base 6). A plurality of electromagnets 1 is provided so as to face the respective magnetic substances 2 fixed to the fixing member 9. In other words, the fixing member 9 (the top plate 5) is held at an intermediate position on the base 6 as a buoyant object in space surrounded by a plurality of electromagnets 1.

FIG. 2B is a plan view illustrating the positional relationship between the electromagnet 1 and the magnetic substance 2. When there are six pairs of the electromagnet 1 and the magnetic substance 2, two pairs of the electromagnet 1 and the magnetic substance 2 may be provided on each of the positive side and the negative side in the Y-axis direction (axial direction of longer stroke of the coarse movement stage 102) and one pair of the electromagnet 1 and the magnetic substance 2 may be provided on each of the positive side and the negative side in the X-axis direction as shown in FIG. 2B using the fixing member 9 as a reference. At this time, it is preferable that the electromagnet 1 and the magnetic substance 2 are uniformly arranged with respect to lines parallel to the X-axis and the Y-axis passing through the central axis of the Z-axis direction on the X-Y plane of the fixing member 9 to allow for generating a magnetic attraction force in balance.

The controller 104 is constituted, for example, by a computer (processor, control substrate including a memory mounted thereon) or the like. The controller 104 generates a driving profile and then control driving of the coarse movement stage 102 and the fine movement stage 103 based on the driving profile. In particular, in the present embodiment, the controller 104 controls driving of the coarse movement stage 102 and the fine movement stage 103 based on different driving profiles. When the stage apparatus 100 is used as a component of, for example, an exposure apparatus, the controller 104 may be integrated with the controller of the exposure apparatus.

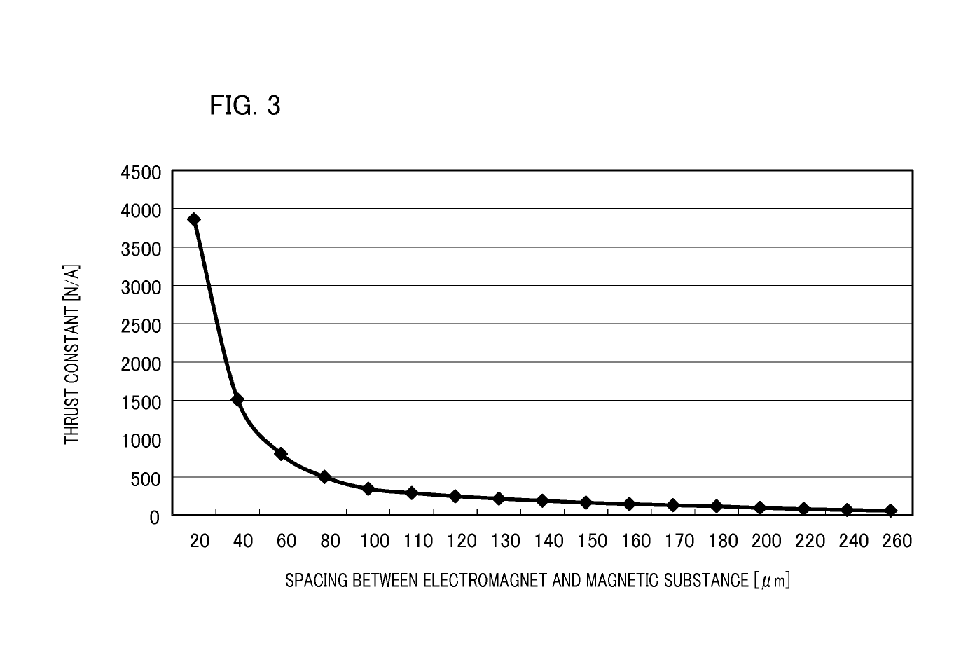

Next, a description will be given of the operation of the stage apparatus 100. Firstly, a description will be given of properties relating to spacing between the electromagnet 1 and the magnetic substance 2 shown in FIGS. 2A and 2B. Here, the spacing between the electromagnet 1 and the magnetic substance 2 is a part where a magnetic path is formed, and, more specifically, is the spacing between the end surface facing the magnetic substance 2 of the yoke 10 on the electromagnet 1 side and the surface of the magnetic substance 2. More simply, the spacing may also be represented as the spacing (stage spacing) between the coarse movement stage 102 and the fine movement stage 103 in the plane direction. FIG. 3 is a graph illustrating actual measured values of a thrust force (thrust constant) per unit current of the electromagnet 1, where the actual measured value may vary depending on the spacing (relative position) between the electromagnet 1 and the magnetic substance 2. It can be seen from this graph that a thrust constant increases, that is, a thrust efficiency improves with decreasing the spacing between the electromagnet 1 and the magnetic substance 2. Here, the force F generated by the electromagnet 1 is represented by the following Formula (1):

$$\begin{matrix}[ Formula 1 ] & \\ F = α \times {i}^{2} \times \frac{1}{{d}^{2}} & ( 1 )\end{matrix}$$

Where “α” represents a constant, “i” represents current fed to the coil 11 of the electromagnet 1, and “d” represents the spacing between the electromagnet 1 and the magnetic substance 2. Here, given that the spacing d is set to 100 μm and the width W of the top plate 5 is set to 500 mm, the stroke (d/(W/2)) of the fine movement stage 103 in the ωz direction is equal to 100/0.250 which is equal to or less than 400 μrad. In order to increase the stroke up to 800 μrad, the spacing d must increase from about 100 μm to 200 μm. However, if the spacing d increases from 100 μm to 200 μm, a thrust constant decreases by about 1/3.5 from 346 N/A to 98 N/A with reference to FIG. 3. Thus, 3.5 times more current needs to be fed to the coil 11 in order to obtain a uniform thrust force at all times. When 3.5 times more current is fed to the coil 11, heat generation is proportional to the square of current and thus increases 12.3 times. This leads to the occurrence of deformation of the top plate 5, which may adversely affect on the accuracy of the stage apparatus 100, resulting in an increase in load on thermal design for suppressing such deformation. Thus, in the present embodiment, a countermeasure is taken to bring the electromagnet 1 which generates a magnetic attraction force upon acceleration or deceleration and the magnetic substance 2 into close proximity as follows with focusing on the fact that a largest amount of heat generation is generated by the fine movement actuator 7 at a timing of acceleration or deceleration.

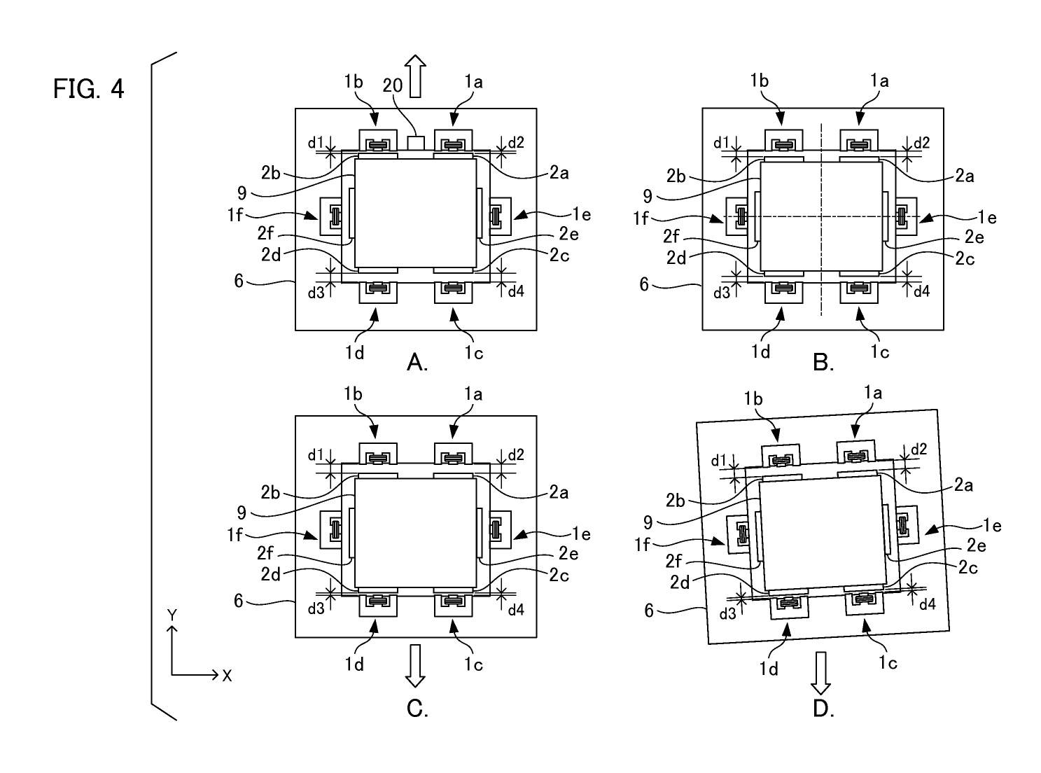

FIGS. 4A to 4D are schematic plan views illustrating the setting state of the spacing d in the present embodiment when the coarse movement stage 102 moves in the positive Y-axis direction. Although no description will be given, the same operation and control as that to be described below can also be made for the movement of the coarse movement stage 102 in the X-axis direction. Here, the pairs of the electromagnet 1 and the magnetic substance 2 which are mainly used when the coarse movement stage 102 moves in the Y-axis direction (when current is fed to the coil 11) are four pairs (pairs including the electromagnets la to 1d) which are mutually opposed to each other in the Y-axis direction.

Firstly, FIG. 4A is a diagram illustrating the state of the coarse movement stage 102 upon acceleration thereof immediately after start of movement thereof. Upon acceleration of the coarse movement stage 102, two electromagnets 1a and 1b which are provided on the front side in the traveling direction are used. In the present embodiment, upon acceleration of the coarse movement stage 102, the electromagnets 1a and 1b are controlled such that the relative position (the position of the fixing member 9 in FIGS. 4A to 4D) of the fine movement stage 103 with respect to the coarse movement stage 102 is offset in the direction of movement of the coarse movement stage 102. More specifically, the electromagnets 1a and 1b and the magnetic substances 2a and 2b are respectively brought into close proximity such that the spacing d satisfies the conditions that d1=d2, d3=d4, and d1<d3. Here, the electromagnets 1a and 1b are controlled independently (based on a different driving profile) of a coarse movement actuator for moving the coarse movement stage 102 in order to move the coarse movement stage 102 and the fine movement stage 103 as described above.

Next, FIG. 4B is a diagram illustrating the state of the coarse movement stage 102 at a constant speed. Upon movement of the coarse movement stage 102 at a constant speed, four electromagnets 1a to 1d are used such that the spacing d becomes equal to each other (d1=d2=d3=d4).

Next, FIG. 4C is a diagram illustrating the state of the coarse movement stage 102 upon deceleration thereof. Upon deceleration of the coarse movement stage 102, two electromagnets 1c and 1d which are provided on the front side in the traveling direction are used. Upon deceleration of the coarse movement stage 102, the electromagnets 1c and 1d are controlled such that the relative position of the fine movement stage 103 with respect to the coarse movement stage 102 is offset in a direction opposite to the direction of movement of the coarse movement stage 102. More specifically, in reverse to the case of acceleration, the electromagnets 1c and 1d and the magnetic substances 2c and 2d are respectively brought into close proximity such that the spacing d satisfies the conditions that d1=d2, d3=d4, and d1>d3.

On the other hand, FIG. 4D is a diagram illustrating the state of the coarse movement stage 102 with it being rotated in the ωz direction. When the fine movement stage 103 rotates in the ωz direction, four electromagnets 1a to 1d are used such that the coarse movement stage 102 rotates to follow the rotational orientation (the amount of rotation) of the fine movement stage 103. In this manner, the electromagnet 1 and the magnetic substance 2 are in opposed parallel relationship and the two adjacent spacings d between the electromagnet 1 and the magnetic substance 2, i.e., the spacings d1 and d2 or the spacings d3 and d4, can be close to equal to each other.

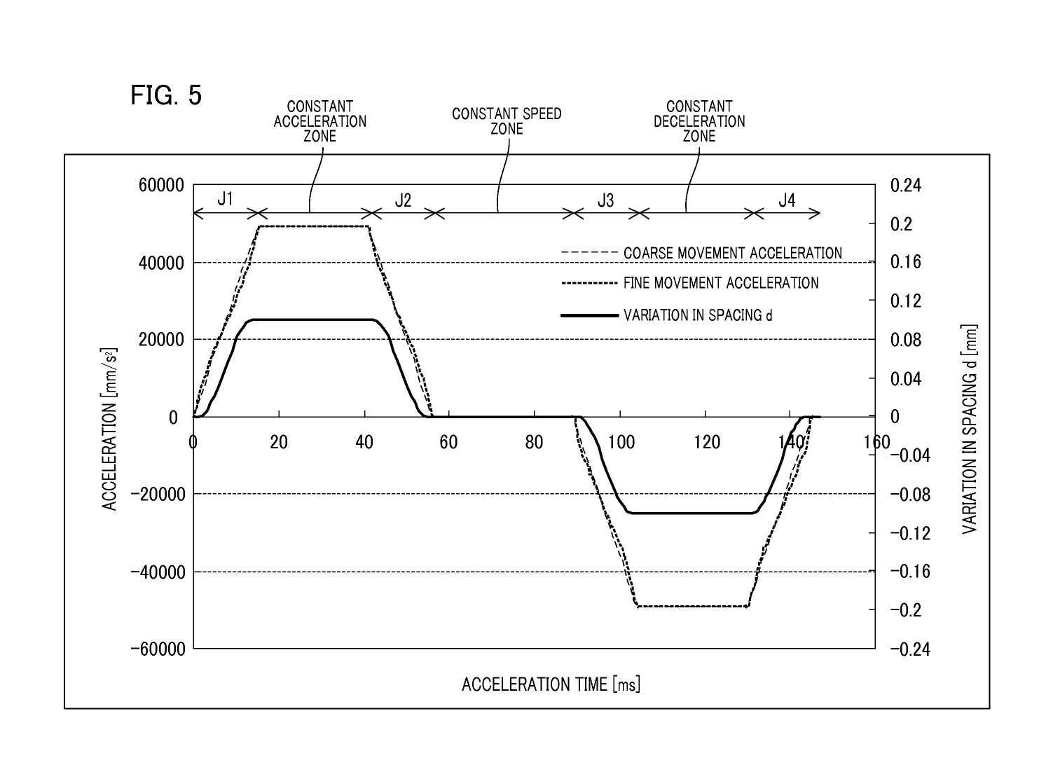

Next, a description will be given of a basic operation performed when the stage apparatus 100 is used in, for example, an exposure apparatus. FIG. 5 is a graph illustrating variation in acceleration and the spacing d with respect to an acceleration time when the spacing d is controlled to be decreased as appropriate as described above during a scan operation upon exposure. Firstly, after the start of movement of the stage, the controller 104 performs control such that the fine movement stage 103 is offset with respect to the coarse movement stage 102 in the traveling direction in the jerk (derivative of acceleration with respect to time) zone 1 where acceleration within the acceleration region increases. Thus, the electromagnets 1a and 1b which are provided on the rear side in the traveling direction as shown in FIG. 4A have a high thrust constant in the constant acceleration zone. Next, the controller 104 performs control such that the fine movement stage 103 is returned to its original position in which the front and back thereof are equalized with respect to the coarse movement stage 102 in the jerk zone 2 where acceleration within the acceleration region decreases. In this manner, the spacings d are equal to each other as shown in FIG. 4B in the constant speed zone immediately after the jerk zone 2, so that a wide stroke can be maintained. Next, the controller 104 performs control such that the fine movement stage 103 is offset with respect to the coarse movement stage 102 in a direction opposite to the direction of movement of the fine movement stage 103 in the jerk zone 3 where acceleration within the deceleration region decreases in contrast to the acceleration region. Thus, the electromagnets 1c and 1d which are provided on the front side in the traveling direction have a high thrust constant in the constant deceleration zone. Next, the controller 104 performs control such that the fine movement stage 103 is returned to its original position in which the front and back thereof are equalized with respect to the coarse movement stage 102 in the jerk zone 4 where acceleration within the deceleration region increases. Through execution of such control by the controller 104, the electromagnet 1 can be used with a high thrust constant while maintaining the stroke during movement of the coarse movement stage 102 and the fine movement stage 103, so that the amount of heat generated in the electromagnet 1 can be suppressed. Such control may be applicable even when the traveling direction is always switched in a constant acceleration state by eliminating the jerk zone 1 and the jerk zone 4 upon switching from deceleration to acceleration in the opposite direction.

As described above, the stage apparatus 100 decreases the spacing d between the electromagnet 1 for generating a magnetic attraction force and the magnetic substance 2 during movement of the coarse movement stage 102 and the fine movement stage 103, in particular, upon acceleration or deceleration thereof. In this manner, the electromagnet 1 can be used with a high thrust constant while maintaining the stroke, so that the amount of heat generated in the electromagnet 1 can be suppressed.

In the present embodiment, a driving profile which is an instruction value for the electromagnet 1 is generated in order to decrease the spacing d between the electromagnet 1 and the magnetic substance 2 upon acceleration or deceleration. As a driving profile, for example, an acceleration profile or a magnetic flux profile calculated from the acceleration profile may be used. Furthermore, magnetic flux feedback control may also be performed.

In the present embodiment, the fine movement stage 103 is driven instead of the coarse movement stage 102 when the spacing d between the electromagnet 1 and the magnetic substance 2 decreases. This is because the fine movement stage 103 has a wide control band so that high speed positioning can be achieved with high precision as compared with the coarse movement stage 102. However, in the present invention, a driving profile which is an instruction value for a coarse movement actuator may also be generated in order to decrease the spacing d between the electromagnet 1 and the magnetic substance 2 upon acceleration or deceleration. As a driving profile, for example, an acceleration profile or a position profile calculated from the acceleration profile may be used. Furthermore, position feedback control may also be performed.

In the present embodiment, the linear motor of the fine movement actuator 7 performs driving in the Z-axis direction and the tilt (ωx, ωy) direction but may also perform driving in the six-axis direction. In this case, a driving profile which is an instruction value for the linear motor of the fine movement actuator 7 may also be generated in order to decrease the spacing d between the electromagnet 1 and the magnetic substance 2 upon acceleration or deceleration. As a driving profile, for example, an acceleration profile or a position profile calculated from the acceleration profile may be used. Furthermore, position feedback control may also be performed.

Also in the present embodiment, the spacing d is positively changed upon acceleration or deceleration but the thrust constant of the electromagnet 1 varies depending on the width (size) of the spacing d, and thus, the controller 104 needs to switch an electromagnet control gain as appropriate. It is preferable that the thrust constant for the spacing d of the single electromagnet 1 is measured in advance using a jig and then the controller 104 performs correction using the measurement value. As can be seen from Formula (1), the measurement value is inversely proportional to the square of the spacing d. Hence, the controller 104 may hold the measurement value as a correction function by the spacing d or may also hold the measurement value as a correction table for the spacing d.

In order to favorably control the spacing d, it is preferable that the stage apparatus 100 includes a sensor (measuring unit) 20 for directly measuring the spacing d as shown in FIG. 4A. For example, a capacitive sensor may be provided on the coarse movement stage 102 so as to directly measure the distance (i.e., spacing d) between the capacitive sensor and the fine movement stage 103 or a laser interferometer may also determine the spacing d as a difference obtained by measuring the coarse movement stage 102 and the fine movement stage 103. Then, the controller 104 determines a correction coefficient for changing a thrust constant depending on the obtained measurement value (actual measured value) of the spacing d so as to reflect the correction coefficient to the actual control.

The method for driving the stage apparatus of the present embodiment includes a step (first generating step) of generating a driving profile of the first driving unit (electromagnet or linear motor of fine movement actuator) or the second driving unit (coarse movement actuator) such that the relative position of the fine movement stage with respect to the coarse movement stage is offset in the direction of movement of the coarse movement stage upon acceleration thereof; a step (second generating step) of generating a driving profile of the first driving unit (electromagnet or linear motor of fine movement actuator) or the second driving unit (coarse movement actuator) such that the relative position of the fine movement stage with respect to the coarse movement stage is offset in a direction opposite to the direction of movement of the coarse movement stage upon deceleration thereof; and a step of controlling the first driving unit or the second driving unit based on the driving profiles generated in the first and second generating steps.

As described above, according to the present embodiment, a stage apparatus that includes a coarse movement stage and a fine movement stage and is advantageous for reducing the amount of heat generated in an actuator for driving the fine movement stage while ensuring the stroke of the fine movement stage may be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-182874 filed on Sep. 4, 2013, and Japanese Patent Application No. 2014-156173 filed on Jul. 31, 2014, which is hereby incorporated by reference herein in its entirety.

What is claimed is:

1. A stage apparatus comprising:
a first stage configured to be movable by a predetermined stroke;
a second stage configured to be movable on the first stage by a stroke shorter than the stroke of the first stage;
a first driving unit configured to include an actuator which generates a thrust force between the first stage and the second stage and has a different thrust constant depending on the relative positions of the first stage and the second stage and to change the relative position of the second stage with respect to the first stage;
a second driving unit configured to change the position of the first stage; and
a controller configured to control the first driving unit or the second driving unit such that the relative position of the second stage with respect to the first stage is offset in the direction of movement of the first stage upon acceleration of the first stage whereas the relative position of the second stage with respect to the first stage is offset in a direction opposite to the direction of movement of the first stage upon deceleration of the first stage.

2. The stage apparatus according to claim 1, wherein the controller controls driving of the first driving unit and the second driving unit based on different profiles.

3. The stage apparatus according to claim 1, wherein the actuator is a plurality of electromagnets which are provided correspondingly to the respective directions of movement of the second stage, the plurality of electromagnets is provided on one side of the first stage or the second stage, and a plurality of magnetic substances facing each of the plurality of electromagnets is provided on the other side of the first stage or the second stage.

4. The stage apparatus according to claim 3, wherein the controller supplies current to the electromagnets such that the spacing between the electromagnet for generating a larger thrust force in the direction of movement of the first stage and the magnetic substance facing the electromagnet is less than the spacing between the other electromagnet and the magnetic substance facing the electromagnet upon acceleration of the first stage whereas the spacing between the electromagnet for generating a larger thrust force in a direction opposite to the direction of movement of the first stage and the magnetic substance facing the electromagnet is less than the spacing between the other electromagnet and the magnetic substance facing the electromagnet upon deceleration of the first stage.

5. The stage apparatus according to claim 4, further comprising:
a measuring unit configured to measure the spacing,
wherein the controller corrects the thrust force generated by the actuator based on the actual measured value of the spacing measured by the measuring unit.

6. The stage apparatus according to claim 4, wherein the first driving unit includes a linear motor which is different from the actuator, and the controller controls the linear motor such that the relative position of the second stage with respect to the first stage is offset in the direction of movement of the first stage upon acceleration of the first stage whereas the relative position of the second stage with respect to the first stage is offset in a direction opposite to the direction of movement of the first stage upon deceleration of the first stage.

7. The stage apparatus according to claim 6, wherein the controller controls the linear motor and the second driving unit such that the relative position of the second stage with respect to the first stage is offset in the direction of movement of the first stage upon acceleration of the first stage whereas the relative position of the second stage with respect to the first stage is offset in a direction opposite to the direction of movement of the first stage upon deceleration of the first stage.

8. The stage apparatus according to claim 7, wherein the controller controls the second driving unit such that the relative position of the second stage with respect to the first stage is offset in the direction of movement of the first stage upon acceleration of the first stage whereas the relative position of the second stage with respect to the first stage is offset in a direction opposite to the direction of movement of the first stage upon deceleration of the first stage.

9. The stage apparatus according to claim 2, wherein the controller drives the first actuator and the second actuator such that the orientation of the first stage is rotated by following the rotational orientation of the second stage.

10. A method for driving a stage apparatus that includes a first stage configured to be movable by a predetermined stroke; a second stage configured to be movable on the first stage by a stroke shorter than the stroke of the first stage; a first driving unit configured to include an actuator which generates a thrust force between the first stage and the second stage and has a different thrust constant depending on the relative positions of the first stage and the second stage and to change the relative position of the second stage with respect to the first stage; and a second driving unit configured to change the position of the first stage, the method comprising:
a first generating step of generating a driving profile of the first driving unit or the second driving unit such that the relative position of the second stage with respect to the first stage is offset in the direction of movement of the first stage upon acceleration of the first stage;
a second generating step of generating a driving profile of the first driving unit or the second driving unit such that the relative position of the second stage with respect to the first stage is offset in a direction opposite to the direction of movement of the first stage upon deceleration of the first stage; and
controlling the first driving unit or the second driving unit based on the driving profiles generated in the first and second generating steps.
